(19) United States
(12) Patent Application Publication
(10) Pub. No.: US 2024/0222273 A1
(43) Pub. Date: Jul. 4, 2024

(54) SEMICONDUCTOR PACKAGE

(71) Applicant: SAMSUNG ELECTRONICS CO., LTD., SUWON-SI, GYEONGGI-DO (KR)

(72) Inventors: HYUN SOO CHUNG, Suwon-si, Gyeonggi-do (KR); DAE-WOO KIM, Suwon-si, Gyeonggi-do (KR); WON-YOUNG KIM, Suwon-si, Gyeonggi-do (KR)

(21) Appl. No.: 18/461,040

(22) Filed: Sep. 5, 2023

(30) Foreign Application Priority Data
Jan. 3, 2023 (KR) 10-2023-0000758

(51) Int. Cl. H01L 23/528; H01L 23/00; H01L 23/31; H01L 23/48; H01L 23/522; H01L 25/065; H10B 80/00

(52) U.S. Cl. CPC H01L 23/528; H01L 23/3107; H01L 23/481; H01L 23/5226; H01L 24/08; H01L 24/13; H01L 25/0657; H10B 80/00; H01L 2224/08145; H01L 2224/13

(57) ABSTRACT

A semiconductor package is provided. The semiconductor package comprises a first semiconductor chip including the first signal wiring structure disposed in an upper surface thereof, and a first power wiring structure disposed in a lower surface thereof, a second semiconductor chip disposed on the first signal wiring structure and including a second signal wiring structure, a second power wiring structure disposed on the second semiconductor chip and a first power connection pillar connecting the first power wiring structure and the second power wiring structure to each other.

### CROSS-REFERENCE TO RELATED APPLICATION

This application claims priority from Korean Patent Application No. 10-2023-0000758 filed on Jan. 3, 2023, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor package.

### Description of Related Art

In accordance with rapid development of the electronics industry and user demand, an electronic device is becoming smaller, lightweight, and multifunctional. Thus, a semiconductor package used in the electrical device is required to be smaller, lightweight, and multifunctional. To this end, two or more types of semiconductor chips are integrated into one semiconductor package, thereby significantly reducing a size of the semiconductor package while achieving high capacity and multi-function of the semiconductor package.

### SUMMARY

In various embodiments, the present disclosure can provide a semiconductor package with improved product reliability.

According to some aspects of the present inventive concept, there is provided a semiconductor package comprising a first semiconductor chip including the first signal wiring structure disposed in an upper surface thereof, and a first power wiring structure disposed in a lower surface thereof, a second semiconductor chip disposed on the first signal wiring structure and including a second signal wiring structure, a second power wiring structure disposed on the second semiconductor chip and a first power connection pillar connecting the first power wiring structure and the second power wiring structure to each other.

According to some aspects of the present inventive concept, there is provided a semiconductor package comprising a first semiconductor chip including a first through-via, a second semiconductor chip disposed on the first semiconductor chip and including a second through-via, a power wiring substrate disposed on the second semiconductor chip and a power connection pillar connecting the first semiconductor chip and the power wiring substrate to each other, wherein the first semiconductor chip includes a first signal wiring structure disposed on a top surface of the first through-via, and a first power wiring structure disposed on a bottom surface of the first through-via, wherein the second semiconductor chip includes a second signal wiring structure disposed on a bottom surface of the second through-via, wherein the second signal wiring structure contacts the first signal wiring structure, wherein the power wiring substrate includes a second power wiring structure disposed on the second through-via, wherein the power connection pillar extends between the first power wiring structure and the second power wiring structure, wherein the power connection pillar is disposed outwardly of the second semiconductor chip.

According to some aspects of the present inventive concept, there is provided a semiconductor package comprising a first semiconductor chip including a first signal wiring structure disposed in an upper surface thereof, a first power wiring structure disposed in a lower surface thereof and a first through-via connected to the first signal wiring structure and the first power wiring structure, a second semiconductor chip including a second signal wiring structure disposed on the first signal wiring structure and a second through-via connected to the second signal wiring structure, a second power wiring structure disposed on the second semiconductor chip and connected to the second through-via, a molding film disposed between the second power wiring structure and the first signal wiring structure so as to surround the second semiconductor chip, a power connection pillar extending through the molding film so as to connect the first power wiring structure and the second power wiring structure to each other, a power wiring substrate disposed on the second power wiring structure and a lower bump disposed on a bottom surface of the first semiconductor chip and connected to the first power wiring structure, wherein a width of the second power wiring structure and a width of the power wiring substrate are equal to each other.

The features of the present disclosure are not limited to the specific features as mentioned herein, but other modifications and changes will be clearly understood by those skilled in the art from descriptions set forth below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a cross-sectional view for illustrating a semiconductor package according to some embodiments.

FIG. 2 is a cross-sectional view for illustrating a semiconductor package according to some other embodiments.

FIG. 3 is a cross-sectional view for illustrating a semiconductor package according to some other embodiments.

FIG. 4 to FIG. 8 are diagrams of intermediate structures corresponding to intermediate steps for illustrating a method for manufacturing a semiconductor package according to some embodiments.

FIG. 9 to FIG. 13 are diagrams of intermediate structures corresponding to intermediate steps for illustrating a method for manufacturing a semiconductor package according to some other embodiments.

### DETAILED DESCRIPTIONS

Hereinafter, embodiments according to the technical idea of the present disclosure will be described with reference to the accompanying drawings.

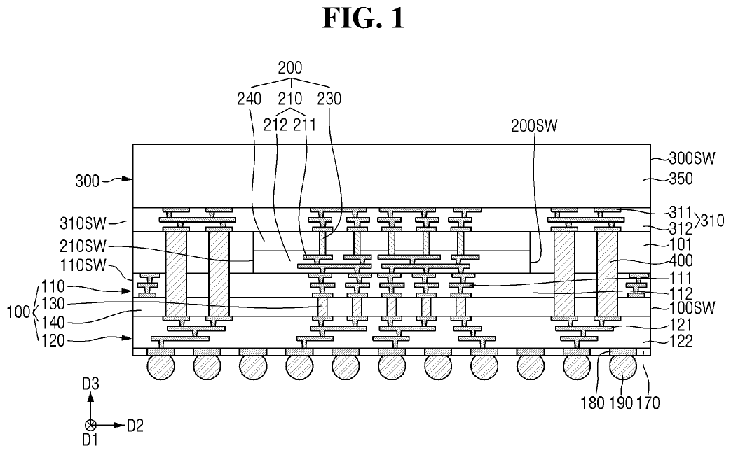

FIG. 1 is a cross-sectional view illustrating a semiconductor package according to some embodiments.

Referring to FIG. 1, a semiconductor package according to some embodiments may include a first semiconductor chip 100, a second semiconductor chip 200, an upper power wiring structure 300, and a power connection pillar 400.

The first semiconductor chip 100 may include a first signal wiring structure 110, a first power wiring structure 120, a first through-via 130 and a first semiconductor substrate 140. A first semiconductor chip 100 can include a first signal wiring structure 110 forming a first (e.g., upper) surface thereof, and a first power wiring structure 120 forming a second (e.g., lower) surface thereof, wherein the second surface is opposite the first surface. The first semiconductor substrate 140 can be interposed between the first signal wiring structure 110 and the first power wiring structure 120.

The first semiconductor substrate 140 may be made of, for example, bulk silicon or SOI (silicon-on-insulator). In another example, the first semiconductor substrate 140 may be a silicon substrate. In still another example, the first semiconductor substrate 140 may include silicon germanium, SGOI (silicon germanium on insulator), indium antimonide, lead telluride compound, indium arsenide, indium phosphide, gallium arsenide or gallium antimonide. However, the present disclosure is not limited thereto.

The first semiconductor substrate 140 may include a conductive area, for example, a well doped with impurities or a structure doped with impurities. The first semiconductor substrate 140 may have various device isolation structures such as a shallow trench isolation (STI) structures.

The first signal wiring structure 110 may be disposed on an upper surface of the first semiconductor substrate 140. The first signal wiring structure 110 may include a plurality of various types of individual devices and interlayer insulating films. The individual devices may include various microelectronic devices, for example, MOSFET (metal-oxide-semiconductor field effect transistor), such as a CMOS transistor (a complementary metal-insulator-semiconductor transistor), a system LSI (large scale integration), a flash memory, DRAM, SRAM, EEPROM, PRAM, MRAM, RRAM, an image sensor such as CIS (CMOS imaging sensor), MEMS (micro-electro-mechanical system), an active device, a passive device, etc.

The first signal wiring structure 110 may be disposed under the second semiconductor chip 200, where the first signal wiring structure 110 can adjoin the second semiconductor chip 200 at an interface. The first signal wiring structure 110 may be disposed between the first semiconductor substrate 140 and the second semiconductor chip 200.

The individual devices of the first signal wiring structure 110 may be electrically connected to a conductive area formed in the first semiconductor substrate 140. Each of the individual devices of the first signal wiring structure 110 may be electrically insulated from other individual devices adjacent thereto via an insulating film. The first signal wiring structure 110 may include a first signal wiring line 111 electrically connecting at least two of the plurality of individual devices to each other or electrically connecting the plurality of individual devices to the conductive area of the first semiconductor substrate 140.

The first signal wiring structure 110 may include the first signal wiring line 111 and a first insulating layer 112. The first signal wiring line 111 may be disposed within the first insulating layer 112. The first signal wiring line 111 may provide an electrical path from a first surface of the first insulating layer 112 to a second surface of the first insulating layer 112 opposite the first surface with a thickness therebetween. The first signal wiring line 111 may provide an electrical connection through the first insulating layer 112, where individual devices of the first signal wiring structure 110 may be electrically connected to the first signal wiring line 111.

The first signal wiring line 111 may include a metal wiring layer and a via plug. For example, the first signal wiring line 111 may have a multilayer structure in which two or more metal wiring layers and two or more via plugs are alternately stacked on top of each other.

The first signal wiring line 111 may include a conductive material. For example, the first signal wiring line 111 may include copper (Cu), aluminum (Al), silver (Ag), tin (Sn), gold (Au), nickel (Ni), lead (Pb), titanium (Ti), or an alloy thereof, but is not limited thereto.

The first insulating layer 112 may be made of a photosensitive insulating material (photoimageable dielectric). For example, the first insulating layer 112 may include a photosensitive polymer. The photosensitive polymer may include, for example, at least one of photosensitive polyimide, polybenzoxazole, phenol-based polymer, or benzocyclobutene-based polymer. In another example, the first insulating layer 112 may include a silicon oxide layer, a silicon nitride layer, or a silicon oxynitride layer.

The first signal wiring structure 110 may include a substrate. The substrate of the first signal wiring structure 110 may be a printed circuit board (PCB) or a ceramic substrate. Although, the present disclosure is not limited thereto.

The substrate of the first signal wiring structure 110 may be made of at least one material selected from phenol resin, epoxy resin, and polyimide. The substrate of the first signal wiring structure 110 may include at least one material selected from tetrafunctional epoxy, polyphenylene ether, epoxy/polyphenylene oxide, BT (bismaleimide triazine), thermount, cyanate ester, and liquid crystal polymer.

The substrate of the first signal wiring structure 110 may include a core material (such as glass fiber, glass cloth, or glass fabric) along with an inorganic filler impregnated with a resin, such as prepreg, ABF (Ajinomoto Build-up Film), FR-4, or BT (Bismaleimide Triazine).

A passivation layer may be formed on the first signal wiring structure 110, so as to protect the first signal wiring line 111 and other structures in the first signal wiring structure 110 from external impact or moisture.

The first power wiring structure 120 may be disposed on a lower surface of the first semiconductor substrate 140. The first power wiring structure 120 may include a plurality of various types of individual devices and interlayer insulating films. The individual devices may include various microelectronic devices, for example, MOSFET (metal-oxide-semiconductor field effect transistor), such as a CMOS transistor (a complementary metal-insulator-semiconductor transistor), a system LSI (large scale integration), a flash memory, DRAM, SRAM, EEPROM, PRAM, MRAM, RRAM, an image sensor such as CIS (CMOS imaging sensor), MEMS (micro-electro-mechanical system), an active device, a passive device, etc.

The individual devices of the first power wiring structure 120 may be electrically connected to a conductive area formed in the first semiconductor substrate 140. Each of the individual devices of the first power wiring structure 120 may be electrically insulated from other individual devices adjacent thereto via an insulating film. The first power wiring structure 120 may include a first power wiring line 121 electrically connecting at least two of the plurality of individual devices to each other or electrically connecting the plurality of individual devices to the conductive area of the first semiconductor substrate 140.

The first power wiring structure 120 may include the first power wiring line 121 and a second insulating layer 122. The first power wiring line 121 may be disposed within the second insulating layer 122. The first power wiring line 121 may provide an electrical path from a first surface of the second insulating layer 122 to a second surface of the second insulating layer 122 opposite the first surface. The first power wiring line 121 may provide an electrical connection through the second insulating layer 122, where individual devices of the first power wiring structure 120 may be electrically connected to the first power wiring line 121.

The first power wiring line 121 may include a conductive material. For example, the first power wiring line 121 may include copper (Cu), aluminum (Al), silver (Ag), tin (Sn), gold (Au), nickel (Ni), lead (Pb), titanium (Ti), or an alloy thereof, but is not limited thereto.

The second insulating layer 122 may be made of a photosensitive insulator (photoimageable dielectric). For example, the second insulating layer 122 may include a photosensitive polymer. The photosensitive polymer may include, for example, at least one of photosensitive polyimide, polybenzoxazole, phenol-based polymer, or benzocyclobutene-based polymer. In another example, the second insulating layer 122 may include a silicon oxide layer, a silicon nitride layer, or a silicon oxynitride layer.

The first power wiring structure 120 may include a substrate. The substrate of the first power wiring structure 120 may be a printed circuit board (PCB) or a ceramic substrate. However, the present disclosure is not limited thereto.

The substrate of the first power wiring structure 120 may be made of at least one material selected from phenol resin, epoxy resin, and polyimide. The substrate of the first power wiring structure 120 may include at least one material selected from tetrafunctional epoxy, polyphenylene ether, epoxy/polyphenylene oxide, BT (bismaleimide triazine), thermount, cyanate ester, and liquid crystal polymer.

The substrate of the first power wiring structure 120 may include a core material (such as glass fiber, glass cloth, or glass fabric) along with an inorganic filler impregnated with a resin, such as prepreg, ABF (Ajinomoto Build-up Film), FR-4, or BT (Bismaleimide Triazine).

A passivation layer may be formed on the first power wiring structure 120, so as to protect the first power wiring line 121 and other structures in the first power wiring structure 120 from external impact or moisture.

The first through-via 130 may extend through the first semiconductor substrate 140. The first through-via 130 may extend from a first (e.g., upper) surface of the first semiconductor substrate 140 toward a second (e.g., lower) surface thereof. The first through-via 130 may be electrically connected to the first power wiring line 121 disposed in the first power wiring structure 120. The first through-via 130 may be electrically connected to a first signal wiring line 111 in the first signal wiring structure 110. The first through-via 130 may be electrically connected to a second signal wiring line 211 in a second signal wiring structure 210, where the first through-via 130 can be electrically connected to the second signal wiring line 211 through the first signal wiring line 111.

The first through-via 130 may include a barrier film constituting a columnar surface of the first through-via 130 and a buried conductive layer filling an inside of the barrier film. The barrier film may include at least one of Ti, TiN, Ta, TaN, Ru, Co, Mn, WN, Ni, or NiB. However, the present disclosure is not limited thereto. The buried conductive layer may include at least one of a Cu alloy such as Cu, CuSn, CuMg, CuNi, CuZn, CuPd, CuAu, CuRe, CuW. W. W alloy, Ni, Ru, or Co. However, the present disclosure is not limited thereto.

In some embodiments, an insulating film may be interposed between the first semiconductor substrate 140 and the first through-via 130. The insulating film may include an oxide film, a nitride film, a carbide film, a polymer, or a combination thereof. However, the present disclosure is not limited thereto.

A lower pad 180 may be disposed on a lower surface of the first semiconductor chip 100. The lower pad 180 may be disposed within a lower passivation layer 170, where the lower passivation layer 170 can be disposed on the lower surface of the second insulating layer 122 of the first semiconductor chip 100. The lower pad 180 may be electrically connected to the first power wiring line 121. The lower pad 180 may include at least one selected from aluminum (Al), copper (Cu), nickel (Ni), tungsten (W), platinum (Pt), and gold (Au).

An outer bump 190 may be electrically connected to the lower pad 180, where the outer bump 190 may receive at least one of a control signal, a power signal, or a ground signal for an operation of each of the first semiconductor chip 100 and the second semiconductor chip 200 from an external source. The outer bump 190 may receive a data signal to be stored in the first semiconductor chip 100 and the second semiconductor chip 200 from an external source, where the outer bump 190 can form an electrical connection to the external source. The outer bump 190 may provide data stored in the first semiconductor chip 100 and the second semiconductor chip 200 to an external device, where the outer bump 190 can form an electrical connection to the external device. For example, the outer bump 190 may have a pillar structure, a ball structure, or a solder layer.

The first signal wiring structure 110 may transfer a data signal between the first semiconductor chip 100 and the second semiconductor chip 200, where the first signal wiring line 111 can electrically connect the first semiconductor chip 100 to the second semiconductor chip 200. For example, the first signal wiring structure 110 may provide a signal related to data stored in the second semiconductor chip 200 to the outer bump 190 to output the signal related to the data stored in the second semiconductor chip 200. In another example, the first signal wiring structure 110 may provide a data signal to be stored in the second semiconductor chip 200, as received from the outer bump 190, to the second semiconductor chip 200.

The first signal wiring structure 110 may transmit a signal to the first semiconductor chip 100 and a signal output from the first semiconductor chip 100, where the transmitted signal may be other than a power signal.

The first signal wiring structure 110 may be directly electrically connected to the first through-via 130, where the first signal wiring line 111 of the first signal wiring structure 110 may be in direct physical contact with the first through-via 130.

The first signal wiring structure 110 may be directly electrically connected to the second signal wiring structure 210, where the first signal wiring line 111 of the first signal wiring structure 110 may be electrically connected to the second signal wiring line 211 of the second signal wiring structure 210. An upper surface of the first signal wiring structure 110 and a lower surface of the second signal wiring structure 210 can be in physical contact with each other. The first signal wiring line 111 of the first signal wiring structure 110 may be in direct physical contact with the second signal wiring line 211.

The first power wiring structure 120 may supply power to the first semiconductor chip 100. For example, the first power wiring structure 120 may provide a power signal received from a source external to the semiconductor package to the first semiconductor chip 100 via the outer bump 190. The first power wiring structure 120 may be a power delivery network (PDN) of the first semiconductor chip 100, where the first power wiring structure 120 may conduct power from an external source to the individual devices of the first signal wiring structure 110.

The first power wiring structure 120 may be directly connected to the first through-via 130. Specifically, the first power wiring line 121 of the first power wiring structure 120 may directly contact the first through-via 130. A component may be not disposed between the first power wiring line 121 and the first through-via 130.

The first power wiring line 121 may supply power received via the lower pad 180 and the outer bump 190 to the first semiconductor chip 100 via the first through-via 130.

The first power wiring structure 120 may be connected to a second power wiring structure 310 via the power connection pillar 400. The first power wiring structure 120 may directly supply power to the second power wiring structure 310 via the power connection pillar 400, where the power connection pillar 400 may extend between the first semiconductor chip 100 and the upper power wiring structure 300, and provide an electrical connection between the first semiconductor chip 100 and the upper power wiring structure 300. The power connection pillar 400 may extend through the first insulating layer 112 and the first semiconductor substrate 140, where the power connection pillar 400 can be electrically insulated from the first semiconductor substrate 140.

The second semiconductor chip 200 may be disposed on the first semiconductor chip 100. The second semiconductor chip 200 may include the second signal wiring structure 210, a second through-via 230, and a second semiconductor substrate 240.

The second signal wiring structure 210 may be disposed on a lower surface of the second semiconductor substrate 240. The second signal wiring structure 210 may include a plurality of various types of individual devices and interlayer insulating films. The individual devices may include various microelectronic devices, for example, MOSFET (metal-oxide-semiconductor field effect transistor), such as a CMOS transistor (a complementary metal-insulator-semiconductor transistor), a system LSI (large scale integration), a flash memory, DRAM, SRAM, EEPROM, PRAM, MRAM, RRAM, an image sensor such as CIS (CMOS imaging sensor), MEMS (micro-electro-mechanical system), an active device, a passive device, etc. The second signal wiring structure 210 may include the second signal wiring line 211 and a third insulating layer 212. The second signal wiring line 211 may be disposed within the third insulating layer 212.

The first semiconductor chip 100 may be an application processor chip or a logic chip. For example, the first semiconductor chip 100 may be a microprocessor, an analog device, a digital signal processor, or an application processor.

The second semiconductor chip 200 may be a memory chip. The second semiconductor chip 200 may be a volatile memory chip such as DRAM (Dynamic Random Access Memory) or SRAM (Static Random Access Memory). In another example, the second semiconductor chip 200 may be a nonvolatile memory chip such as PRAM (Phase-change RAM), MRAM (Magnetoresistive RAM), FeRAM (FerroelectricRAM) or RRAM (Resistive RAM). In still another example, the second semiconductor chip 200 may be HBM (High Bandwidth Memory).

A width of the second semiconductor chip 200 may be smaller than that of the first semiconductor chip 100. Specifically, a width in the second direction D2 of the second semiconductor chip 200 may be smaller than that of the first semiconductor chip 100. A sidewall 200SW of the second semiconductor chip 200 may be positioned inwardly of a sidewall 100SW of the first semiconductor chip 100.

Descriptions about the second through-via 230 and the second semiconductor substrate 240 are substantially the same as those about the first through-via 130 and the first semiconductor substrate 140, and thus are omitted.

The second through-via 230 may extend through the second semiconductor substrate 240. The second through-via 230 may be connected to a second power wiring line 311 disposed in the second power wiring structure 310. The second through-via 230 may be connected to the second signal wiring line 211 in the third insulating layer 212 of the second signal wiring structure 210.

The second signal wiring structure 210 may be disposed on the first signal wiring structure 110. A lower surface of the second signal wiring structure 210 may be coplanar with an upper surface of the first signal wiring structure 110. The lower surface of the second signal wiring structure 210 may contact the upper surface of the first signal wiring structure 110, where the second signal wiring structure 210 can form an interface with the first signal wiring structure 110.

The second signal wiring structure 210 may be directly connected to the first signal wiring structure 110, where the second signal wiring line 211 of the second signal wiring structure 210 may directly contact the first signal wiring line 111 of the first signal wiring structure 110. A component may not be disposed between the second signal wiring structure 210 and the first signal wiring structure 110.

A width of the second signal wiring structure 210 may be smaller than a width of the first signal wiring structure 110. Specifically, a width in the second direction D2 of the second signal wiring structure 210 may be smaller than that of the first signal wiring structure 110. A sidewall 210SW of the second signal wiring structure may be positioned inwardly of a sidewall 110SW of the first signal wiring structure. The power connection pillar 400 may extend through at least a portion of the first semiconductor chip 100, but not the second semiconductor chip 200.

The second signal wiring structure 210 may transfer a data signal between the first semiconductor chip 100 and the second semiconductor chip 200, where the second signal wiring line 211 can electrically connect the first semiconductor chip 100 to the second semiconductor chip 200. For example, the second signal wiring structure 210 may provide a signal related to data stored in the second semiconductor chip 200 to the first signal wiring structure 110 to output the signal related to data stored in the second semiconductor chip 200. In another example, the second signal wiring structure 210 may provide a data signal to be stored in the second semiconductor chip 200 as received from the outer bump 190 to the second semiconductor chip 200.

The second signal wiring structure 210 may transmit a signal to the second semiconductor chip 200 and a signal output from the second semiconductor chip 200, where the transmitted signal may be other than a power signal.

The second semiconductor chip 200 may be surrounded with the molding film 101. The molding film 101 may be disposed on the sidewall 200SW of the second semiconductor chip. The molding film 101 may include, for example, an oxide.

The upper power wiring structure 300 may be disposed on the second semiconductor chip 200. The upper power wiring structure 300 may include the second power wiring structure 310 and a power wiring substrate 350.

A width of the upper power wiring structure 300 may be greater than that of the second semiconductor chip 200. Specifically, a width in the second direction D2 of the upper power wiring structure 300 may be greater than that of the second semiconductor chip 200. A sidewall 300SW of the upper power wiring structure may be positioned outwardly of the sidewall 200SW of the second semiconductor chip. The upper power wiring structure 300 may be disposed on the molding film 101. In FIG. 1, it is illustrated that the width of the upper power wiring structure 300 is equal to the width of the first semiconductor chip 100. However, embodiments are not limited thereto.

The second power wiring structure 310 may be disposed on the second semiconductor chip 200. Specifically, the second power wiring structure 310 may be disposed on the second semiconductor substrate 240. The second power wiring structure 310 may be connected to the second through-via 230, where the second power wiring line 311 of the second power wiring structure 310 may directly contact the second through-via 230. The second power wiring structure 310 may include the second power wiring line 311 and a fourth insulating layer 312. The second power wiring line 311 may be disposed within the fourth insulating layer 312.

A width of the second power wiring structure 310 may be greater than a width of the second signal wiring structure 210. A sidewall 310SW of the second power wiring structure may be positioned outwardly of the sidewall 210SW of the second signal wiring structure.

The second power wiring structure 310 may be disposed under the power wiring substrate 350. The second power wiring structure 310 may be connected to the first power wiring structure 120 via the power connection pillar 400. The power wiring substrate 350 can include a second power wiring structure 310 disposed on the second through-via 230.

The second power wiring structure 310 may supply power to the second semiconductor chip 200. For example, the second power wiring structure 310 may provide a power signal received from a source external to the semiconductor package to the second semiconductor chip 200 via the outer bump 190. The second power wiring structure 310 may be a power delivery network (PDN) of the second semiconductor chip 200. The second power wiring structure 310 may directly receive a power signal via the first power wiring structure 120 and the power connection pillar 400.

The power wiring substrate 350 may provide a power signal to the second power wiring structure 310. The power wiring substrate 350 may include wirings and devices. The wirings and the devices of the power wiring substrate 350 may be connected to the second power wiring structure 310. The power wiring substrate 350 may provide power to the first semiconductor chip 100 and the second semiconductor chip 200 via the power connection pillar 400.

The power connection pillar 400 may extend between the first semiconductor chip 100 and the upper power wiring structure 300. For example, the power connection pillar 400 may extend in a third direction D3 perpendicular to the first semiconductor chip 100. The power connection pillar 400 may be disposed outside the second semiconductor chip 200. The power connection pillar 400 may be positioned outwardly of the sidewall 200SW of the second semiconductor chip. The power connection pillar 400 may be disposed between the sidewall 100SW of the first semiconductor chip and the sidewall 200SW of the second semiconductor chip. The power connection pillar 400 may be disposed between the sidewall 300SW of the upper power wiring structure and the sidewall 200SW of the second semiconductor chip. The power connection pillar 400 may be spaced apart from the second semiconductor chip 200, where the molding film 101 may be disposed between the power connection pillar 400 and the second semiconductor chip 200. The first power connection pillar can be spaced apart from the second semiconductor chip in a first direction and extends in a second direction intersecting the first direction.

The power connection pillar 400 may electrically connect the first semiconductor chip 100 and the upper power wiring structure 300 to each other. Specifically, the power connection pillar 400 may connect the first power wiring structure 120 and the second power wiring structure 310 to each other. A lower surface of the power connection pillar 400 may be coplanar with an upper surface of the first power wiring structure 120. An upper surface of the power connection pillar 400 and a lower surface of the second power wiring structure 310 may be coplanar with each other. A lower surface of the power connection pillar 400 can be coplanar with a lower surface of the first through-via 130. An upper surface of the power connection pillar 400 can be coplanar with a upper surface of the second through-via 230. The power connection pillar 400 may contact the first power wiring line 121 and the second power wiring line 311.

The power connection pillar 400 may extend through the molding film 101. A portion of the power connection pillar 400 may be surrounded with the molding film 101. The power connection pillar 400 may extend through a portion of the first semiconductor chip 100. The power connection pillar 400 may extend through the first signal wiring structure 110 and the first semiconductor substrate 140 of the first semiconductor chip 100.

The power connection pillar 400 may provide power required for an operation of the second semiconductor chip 200 to the second semiconductor chip 200. For example, the power connection pillar 400 may provide a power signal provided to the second semiconductor chip 200 to the second power wiring structure 310. The second semiconductor chip 200 may receive a power signal via the second power wiring structure 310.

The power connection pillar 400 may include a conductive material. For example, the power connection pillar 400 may include copper (Cu).

The first power wiring structure 120 may transmit and receive a power signal among a plurality of signals involved in an operation of the first semiconductor chip 100 to and from the first semiconductor chip 100. The first power wiring structure 120 may transmit and receive only a power signal. The second power wiring structure 310 may transmit and receive a power signal among a plurality of signals involved in an operation of the second semiconductor chip 200 to and from the second semiconductor chip 200. The second power wiring structure 310 may transmit and receive only a power signal.

A power signal and signals other than the power signal may be separately provided to the semiconductor chips via the individual wiring structures. Thus, the signals may be stably provided thereto. However, when a power signal and signals other than the power signal are provided to the semiconductor chips via a single wiring structure, the wirings may be acceptable. On the contrary, when a power signal and signals other than power signal are separately provided to the semiconductor chips via the individual wiring structures, the wirings may not be acceptable. Accordingly, the power signal and signals other than the power signal may be stably transmitted to the semiconductor chips.

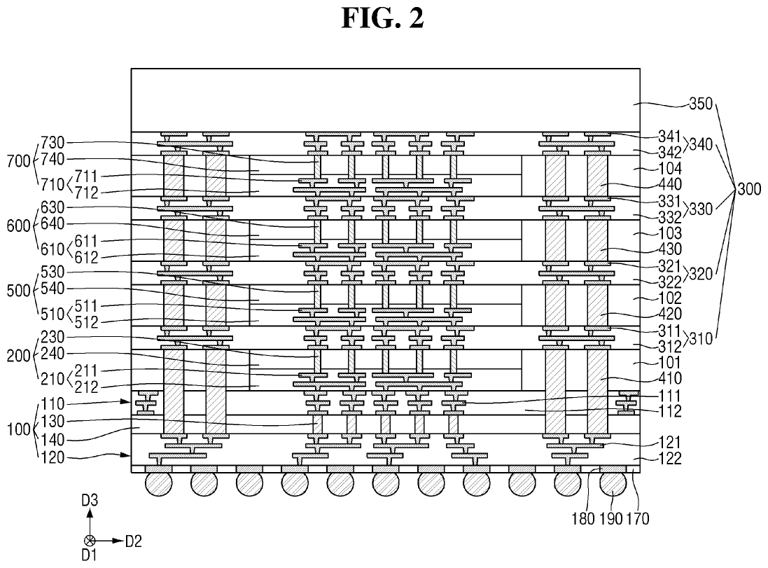

FIG. 2 is a cross-sectional view for illustrating a semiconductor package according to some other embodiments. For the convenience of description, differences thereof from the descriptions as set forth above with reference to FIG. 1 will be mainly set forth below.

Referring to FIG. 2, a semiconductor package according to some embodiments may include a first semiconductor chip to a fifth semiconductor chip 100, 200, 500, 600, and 700, the upper power wiring structure 300, a first power connection pillar 410 to a fourth power connection pillar 440, the first signal wiring structure 110, the second signal wiring structure 210, a third signal wiring structure 510, a fourth signal wiring structure 610, and a fifth signal wiring structure 710.

The first semiconductor chip to the fifth semiconductor chip 100, 200, 500, 600, and 700 may be sequentially stacked. For example, the second semiconductor chip 200 may be disposed on the first semiconductor chip 100. The third semiconductor chip 500 may be disposed on the second semiconductor chip 200. The fourth semiconductor chip 600 may be disposed on the third semiconductor chip 500. The fifth semiconductor chip 700 may be disposed on the fourth semiconductor chip 600.

The third signal wiring structure 510 may include the third signal wiring line 511 and an eighth insulating layer 512. The third signal wiring line 511 may be disposed within the eighth insulating layer 512.

The fourth signal wiring structure 610 may include the fourth signal wiring line 611 and a nineth insulating layer 612. The fourth signal wiring line 611 may be disposed within the nineth insulating layer 612.

The fifth signal wiring structure 710 may include the fifth signal wiring line 711 and a tenth insulating layer 712. The fifth signal wiring line 711 may be disposed within the tenth insulating layer 712.

A width of each of the second semiconductor chip 200 and the third semiconductor chip 500 to fifth semiconductor chips 700 may be smaller than a width of the first semiconductor chip 100. Specifically, a width in the second direction D2 of each of the second semiconductor chip 200 and the third semiconductor chip to the fifth semiconductor chip 500 to 700 may be smaller than that of the first semiconductor chip 100.

The second semiconductor chip 200 may be surrounded with a first molding film 101. The third semiconductor chip 500 may be surrounded with a second molding film 102. The fourth semiconductor chip 600 may be surrounded with a third molding film 103. The fifth semiconductor chip 700 may be surrounded with a fourth molding film 104.

Descriptions about each of the third semiconductor chip 500 to the fifth semiconductor chip 700 are substantially the same as the descriptions about the second semiconductor chip 200.

The upper power wiring structure 300 may include the second power wiring structure 310, a third power wiring structure 320, a fourth power wiring structure 330, and a fifth power wiring structure 340. The second power wiring structure 310 can be interposed between the third semiconductor chip 500 and the second semiconductor chip 200. The third power wiring structure 320 can be interposed between the third semiconductor chip 500 and the fourth semiconductor chip 600. The fourth power wiring structure 330 can be interposed between the fourth semiconductor chip 600 and the fifth semiconductor chip 700.

The upper power wiring structure 300 transmits a power signal for an operation of each of the second semiconductor chip 200, the third semiconductor chip 500, the fourth semiconductor chip 600, and the fifth semiconductor chip 700 to each of the second semiconductor chip 200, the third semiconductor chip 500, the fourth semiconductor chip 600, and the fifth semiconductor chip 700. The upper power wiring structure 300 may transmit and receive only a power signal.

The second power wiring structure 310 may be disposed on the second semiconductor chip 200. The second power wiring structure 310 may provide a power signal to the second semiconductor chip 200. The second power wiring structure 310 may directly contact the second semiconductor chip 200. The second power wiring structure 310 may be electrically connected to the second through-via 230 of the second semiconductor chip 200. The second power wiring structure 310 may include the second power wiring line 311 and a fourth insulating layer 312. The second power wiring line 311 may be disposed within the fourth insulating layer 312.

The third power wiring structure 320 may be disposed on the third semiconductor chip 500. The third power wiring structure 320 may provide a power signal to the third semiconductor chip 500. The third power wiring structure 320 may directly contact the third semiconductor chip 500. The third power wiring structure 320 may be electrically connected to a third through-via 530 of the third semiconductor chip 500. The third power wiring structure 320 may include the third power wiring line 321 and a fifth insulating layer 322. The third power wiring line 321 may be disposed within the fifth insulating layer 322.

The fourth power wiring structure 330 may be disposed on the fourth semiconductor chip 600. The fourth power wiring structure 330 may provide a power signal to the fourth semiconductor chip 600. The fourth power wiring structure 330 may directly contact the fourth semiconductor chip 600. The fourth power wiring structure 330 may be electrically connected to a fourth through-via 630 of the fourth semiconductor chip 600. The fourth power wiring structure 330 may include the fourth power wiring line 331 and a sixth insulating layer 332. The fourth power wiring line 331 may be disposed within the sixth insulating layer 332.

The fifth power wiring structure 340 may be disposed on the fifth semiconductor chip 700. The fifth power wiring structure 340 may be a portion of the power wiring substrate 350. The fifth power wiring structure 340 may provide a power signal to the fifth semiconductor chip 700. The fifth power wiring structure 340 may directly contact the fifth semiconductor chip 700. The fifth power wiring structure 340 may be electrically connected to a fifth through-via 730 of the fifth semiconductor chip 700. The fifth power wiring structure 340 may include the fifth power wiring line 341 and a seventh insulating layer 342. The fourth power wiring line 331 may be disposed within the seventh insulating layer 342.

The first power connection pillar 410 may connect the first power wiring structure 120 and the second power wiring structure 310 to each other. The first power connection pillar 410 may extend between the first power wiring structure 120 and the second power wiring structure 310. The first power connection pillar 410 may extend through the first molding film 101.

The second power connection pillar 420 may connect the second power wiring structure 310 and the third power wiring structure 320 to each other. The second power connection pillar 420 may extend between the second power wiring structure 310 and the third power wiring structure 320. The second power connection pillar 420 may extend through the second molding film 102.

The third power connection pillar 430 may connect the third power wiring structure 320 and the fourth power wiring structure 330 to each other. The third power connection pillar 430 may extend between the third power wiring structure 320 and the fourth power wiring structure 330. The third power connection pillar 430 may extend through the third molding film 103.

The fourth power connection pillar 440 may connect the fourth power wiring structure 330 and the fifth power wiring structure 340 to each other. The fourth power connection pillar 440 may extend between the fourth power wiring structure 330 and the fifth power wiring structure 340. The fourth power connection pillar 440 may extend through the fourth molding film 104.

The second power wiring structure 310 may receive a power signal of the second semiconductor chip 200 from the first power wiring structure 120 via the first power connection pillar 410. Specifically, the power signal of the second semiconductor chip 200 may be provided to the first power wiring structure 310 via the outer bump 190. The power signal of the second semiconductor chip 200 provided to the first power wiring structure 310 may be provided to the second power wiring structure 310 via the first power connection pillar 410. The second power wiring structure 310 may provide the power signal to the second semiconductor chip 200. The second power wiring structure 310 may provide power for an operation of the second semiconductor chip 200 thereto.

The third power wiring structure 320 may receive a power signal of the third semiconductor chip 500 from the first power wiring structure 120 via the first power connection pillar 410 and the second power connection pillar 420. Specifically, the power signal of the third semiconductor chip 500 may be provided to the first power wiring structure 310 via the outer bump 190. The power signal of the third semiconductor chip 500 provided to the first power wiring structure 310 may be provided to the third power wiring structure 320 via the first power connection pillar 410 and the second power connection pillar 420. The third power wiring structure 320 may provide the power signal to the third semiconductor chip 500. The third power wiring structure 320 may provide power for an operation of the third semiconductor chip 500 thereto.

The fourth power wiring structure 330 may receive a power signal of the fourth semiconductor chip 600 from the first power wiring structure 120 via the first power connection pillar 410, the second power connection pillar 420, and the third power connection pillar 430. Specifically, the power signal of the fourth semiconductor chip 600 may be provided to the first power wiring structure 310 via the outer bump 190. The power signal of the fourth semiconductor chip 600 provided to the first power wiring structure 310 may be provided to the fourth power wiring structure 330 via the first power connection pillar 410, the second power connection pillar 420, and the third power connection pillar 430. The fourth power wiring structure 330 may provide the power signal to the fourth semiconductor chip 600. The fourth power wiring structure 330 may provide power required for operation of the fourth semiconductor chip 600 thereto.

The fifth power wiring structure 340 may receive a power signal of the fifth semiconductor chip 700 from the first power wiring structure 120 via the first power connection pillar 410, the second power connection pillar 420, the third power connection pillar 430, and the fourth power connection pillar 440. Specifically, the power signal of the fifth semiconductor chip 700 may be provided to the first power wiring structure 310 via the outer bump 190. The power signal of the fifth semiconductor chip 700 provided to the first power wiring structure 310 may be provided to the fifth power wiring structure 340 via the first power connection pillar 410, the second power connection pillar 420, the third power connection pillar 430, and the fourth power connection pillar 440. The fifth power wiring structure 340 may provide the power signal to the fifth semiconductor chip 700. The fifth power wiring structure 340 may provide power for an operation of the fifth semiconductor chip 700 thereto.

The first signal wiring structure 110, the second signal wiring structure 210, the third signal wiring structure 510, the fourth signal wiring structure 610 and the fifth signal wiring structure 710 may transmit a control signal or a ground signal, etc. for operating the first semiconductor chip to the fifth semiconductor chip 100, 200, 500, 600, and 700 thereto, respectively. Further, the first signal wiring structure 110, the second signal wiring structure 210, the third signal wiring structure 510, the fourth signal wiring structure 610 and the fifth signal wiring structure 710 may respectively transmit signals respectively output from the first semiconductor chip to the fifth semiconductor chip 100, 200, 500, 600, and 700 to the outer bump 190.

The first signal wiring structure 110, the second signal wiring structure 210, the third signal wiring structure 510, the fourth signal wiring structure 610 and the fifth signal wiring structure 710 may respectively transmit or receive signals except for the power signal among a plurality of signals for operating the first semiconductor chip 100, the second semiconductor chip 200, and the third semiconductor chip to the fifth semiconductor chip 500 to 700 thereto or therefrom.

The first power wiring structure 120, the second power wiring structure 310, the third power wiring structure 320, the fourth power wiring structure 330, and the fifth power wiring structure 340 may respectively transmit or receive only the power signals among the plurality of signals for operating the first semiconductor chip 100, the second semiconductor chip 200, and the third semiconductor chip to the fifth semiconductor chip 500 to 700 thereto or therefrom.

In this way, a power signal and signals other than the power signal may be separately provided to the semiconductor chips via the individual wiring structures. Thus, the signals may be stably provided thereto. However, when a power signal and signals other than the power signal are provided to the semiconductor chips via a single wiring structure, the wirings may be fine. On the contrary, when a power signal and signals other than power signal are separately provided to the semiconductor chips via the individual wiring structures, the wirings may not be fine. Accordingly, the power signal and the signals other than the power signal may be stably transmitted to the semiconductor chips.

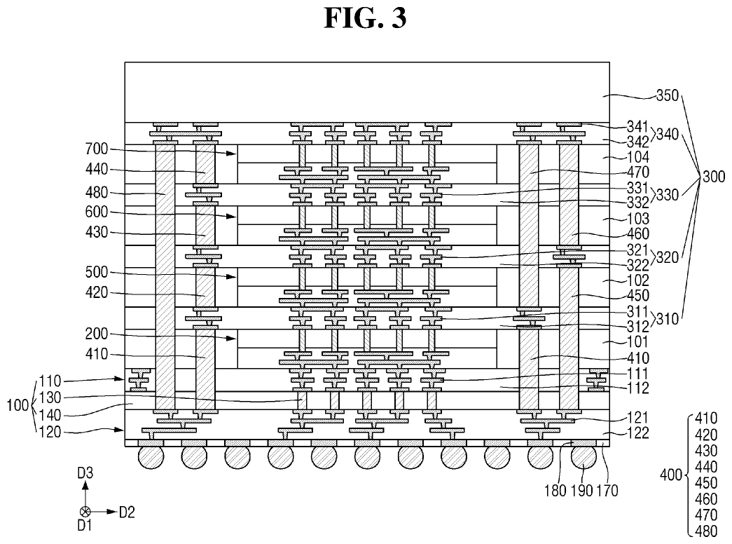

FIG. 3 is a cross-sectional view for illustrating a semiconductor package according to some other embodiments. For the convenience of description, differences thereof from the descriptions as set forth above with reference to FIG. 1 and FIG. 2 will be mainly set forth below.

Referring to FIG. 3, a semiconductor package according to some embodiments may include a first power connection pillar to an eighth power connection pillar 410 to 480.

The fifth power connection pillar 450 may connect the first power wiring structure 120 and the third power wiring structure 320 to each other. The fifth power connection pillar 450 may extend between the first power wiring structure 120 and the third power wiring structure 320. The fifth power connection pillar 450 may extend through the first signal wiring structure 110, the second power wiring structure 310, the first molding film 101 and the second molding film 102.

The third power wiring structure 320 may receive a power signal of the third semiconductor chip 500 from the first power wiring structure 120 via the sixth power connection pillar 460.

The sixth power connection pillar 460 may connect the third power wiring structure 320 and the fifth power wiring structure 340 to each other. The sixth power connection pillar 460 may extend between the third power wiring structure 320 and the fifth power wiring structure 340. The sixth power connection pillar 460 may extend through the fourth power wiring structure 330, the third molding film 103, and the fourth molding film 104.

The fifth power wiring structure 340 may receive a power signal of the fifth semiconductor chip 700 from the third power wiring structure 320 via the sixth power connection pillar 460. The third power wiring structure 320 may receive the power signal of the fifth semiconductor chip 700 from the first power wiring structure 120 via the first power connection pillar 410 and the second power connection pillar 420.

The seventh power connection pillar 470 may connect the second power wiring structure 310 and the fifth power wiring structure 340 to each other. The seventh power connection pillar 470 may extend between the second power wiring structure 310 and the fifth power wiring structure 340. The seventh power connection pillar 470 may extend through the third power wiring structure 320, the fourth power wiring structure 330, the third molding film 103, and the fourth molding film 104.

The fifth power wiring structure 340 may receive the power signal of the fifth semiconductor chip 700 from the second power wiring structure 310 via the seventh power connection pillar 470. The second power wiring structure 310 may receive the power signal of the fifth semiconductor chip 700 from the first power wiring structure 120 via the first power connection pillar 410.

The eighth power connection pillar 480 may connect the first power wiring structure 120 and the fifth power wiring structure 340 to each other. The eighth power connection pillar 480 may extend between the first power wiring structure 120 and the fifth power wiring structure 340. The eighth power connection pillar 480 may extend through the first signal wiring structure 110, the second power wiring structure to the fourth power wiring structure 310 to 330, and the first molding film to the fourth molding film 101 to 104.

The fifth power wiring structure 340 may directly receive the power signal of the fifth semiconductor chip 700 from the first power wiring structure 120 via the eighth power connection pillar 480.

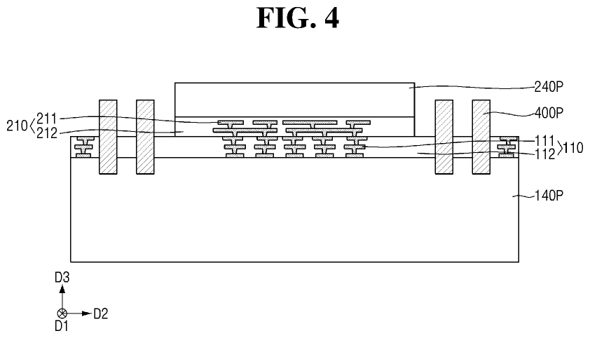

FIG. 4 to FIG. 8 are diagrams of intermediate structures corresponding to intermediate steps for illustrating a method for manufacturing a semiconductor package according to some embodiments. For reference, FIG. 4 to FIG. 8 are drawings for illustrating a method for manufacturing the semiconductor package as shown in FIG. 1.

Referring to FIG. 4, the first signal wiring structure 110, the second signal wiring structure 210, a second pre-semiconductor substrate 240P, and a pre-power connection pillar 400P can be formed on a first pre-semiconductor substrate 140P.

The pre-power connection pillar 400P may extend through a portion of the first pre-semiconductor substrate 140P. The pre-power connection pillar 400P may extend through the first signal wiring structure 110. The pre-power connection pillar 400P may be positioned outwardly the second signal wiring structure 210 and the second pre-semiconductor substrate 240P.

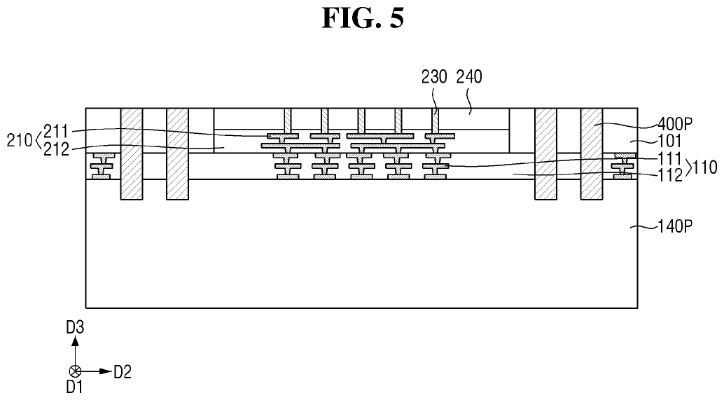

Referring to FIG. 5, the second through-via 230 and the second semiconductor substrate 240 can be formed.

The first molding film 101 may be formed to cover the pre-power connection pillar 400P. Subsequently, the second through-via 230 may be formed in the second pre-semiconductor substrate 240P. An upper surface of each of the pre-power connection pillar 400P, the second pre-semiconductor substrate 240P, and the second through-via 230 may be removed to form the second through-via 230 and the second semiconductor substrate 240.

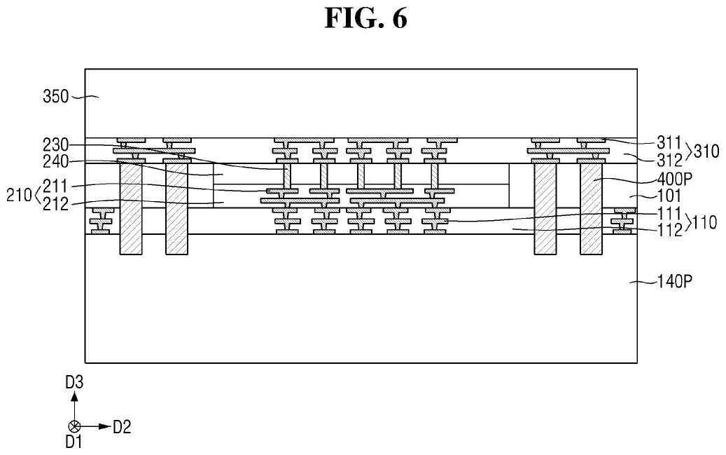

Referring to FIG. 6, the second power wiring structure 310 and power wiring substrate 350 can be formed.

The second power wiring structure 310 may be formed on the pre-power connection pillar 400P, the second semiconductor substrate 240 and the first molding film 101 so that the second power wiring line 311 is connected to the pre-power connection pillar 400P.

For example, the second power wiring structure 310 and the power wiring substrate 350 may be formed separately. The second power wiring structure 310 and the power wiring substrate 350 formed separately may be bonded to the second semiconductor substrate 240 and the pre-power connection pillar 400P.

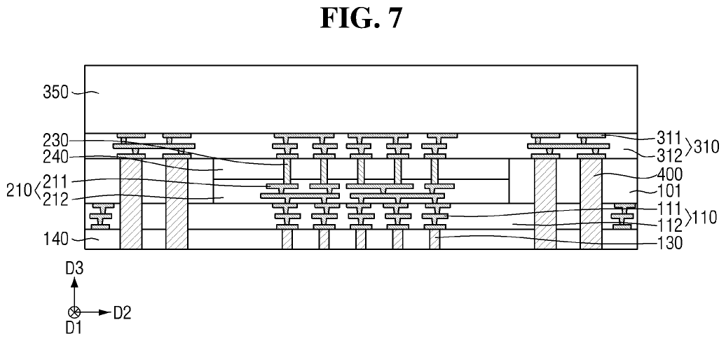

Referring to FIG. 7, the first through-via 130 and power connection pillar 400 can be formed.

Specifically, the first through-via 130 may be formed in the first pre-semiconductor substrate 140P. Subsequently, the first semiconductor substrate 140 and the power connection pillar 400 may be formed by removing a lower surface of the first pre-semiconductor substrate 140P. The power wiring substrate 350 may be formed on the second power wiring structure 310.

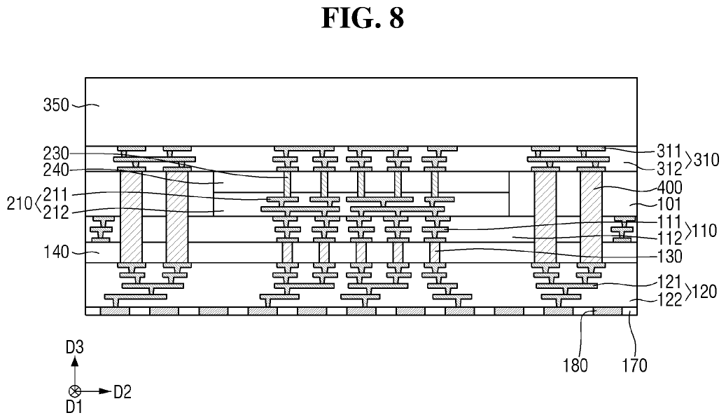

Referring to FIG. 8, the first power wiring structure 120 and the lower pad 180 can be formed.

The first power wiring structure 120 may be formed under the first semiconductor substrate 140 so as to be connected to the first through-via 130 and the power connection pillar 400.

Subsequently, referring to FIG. 1, the outer bump 190 may be formed.

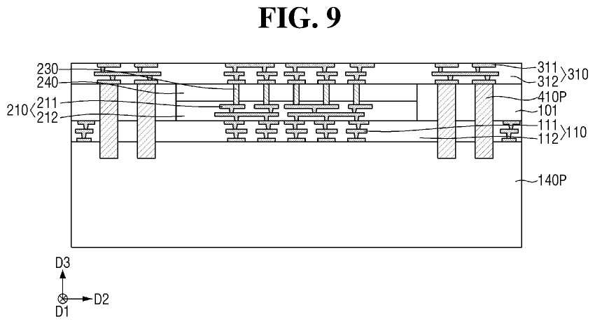

FIG. 9 to FIG. 13 are diagrams of intermediate structures corresponding to intermediate steps for illustrating a method for manufacturing a semiconductor package according to some other embodiments. For reference, FIG. 9 to FIG. 13 are drawings for illustrating a method for manufacturing the semiconductor package as shown in FIG. 2. Further, for reference, FIG. 9 shows a step after FIG. 5. For the convenience of description, differences thereof from the descriptions as set forth above with reference to FIG. 4 to FIG. 8 will be mainly set forth below.

Referring to FIG. 5 and FIG. 9, the second power wiring structure 310 can be formed.

The second power wiring structure 310 may be formed on the pre-power connection pillar 400P, the second semiconductor substrate 240 and the first molding film 101 so that the second power wiring line 311 is connected to a first pre-power connection pillar 410P.

The first pre-power connection pillar 410P in FIG. 9 may correspond to the pre-power connection pillar 400P in FIG. 5.

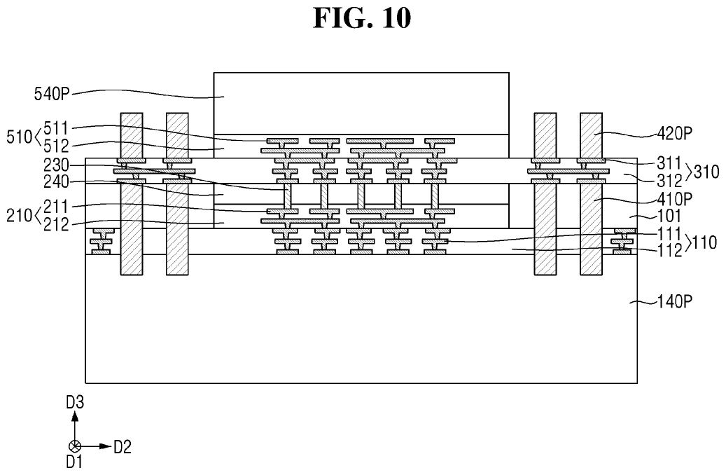

Referring to FIG. 10, the third signal wiring structure 510, a third pre-semiconductor substrate 540P, and a second pre-power connection pillar 420P can be formed.

The second pre-power connection pillar 420P may be formed outwardly of the third signal wiring structure 510. The second pre-power connection pillar 420P may be formed on the second power wiring structure 310 so as to be connected to the second power wiring line 311.

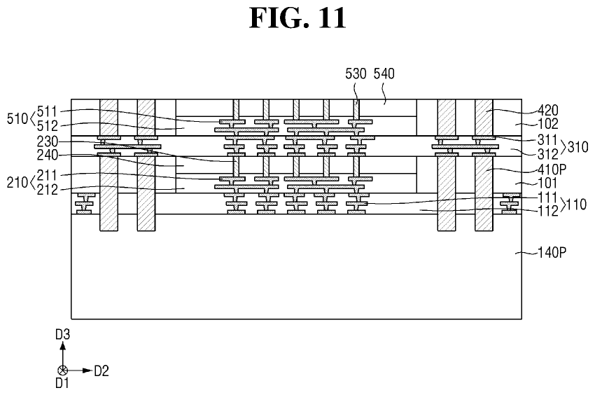

Referring to FIG. 11, the third through-via 530, the third semiconductor substrate 540 and the second power connection pillar 420 can be formed.

The second molding film 102 may be formed to cover the second pre-power connection pillar 420P. Subsequently, the third through-via 530 may be formed in the third pre-semiconductor substrate 540P. An upper surface of each of the second pre-power connection pillar 420P, the third pre-semiconductor substrate 540P, and the third through-via 530 may be removed to form the third through-via 530 and the third semiconductor substrate 540.

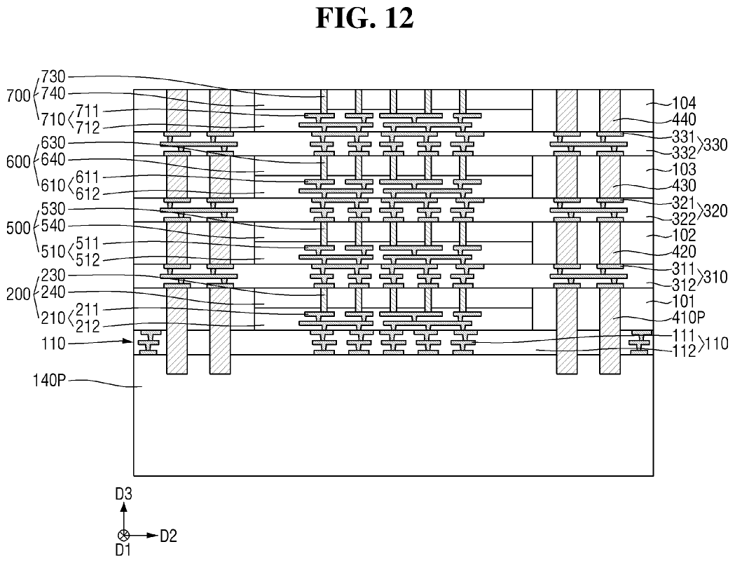

Referring to FIG. 12, the fourth semiconductor chip 600, the fifth semiconductor chip 700, the third power connection pillar 430, and the fourth power connection pillar 440 can be formed.

The steps of FIG. 9 to FIG. 11 may be repeated to form the third power wiring structure 320, the fourth power wiring structure 330, the fourth semiconductor chip 600, the fifth semiconductor chip 700, the third power connection pillar 430 and the fourth power connection pillar 440.

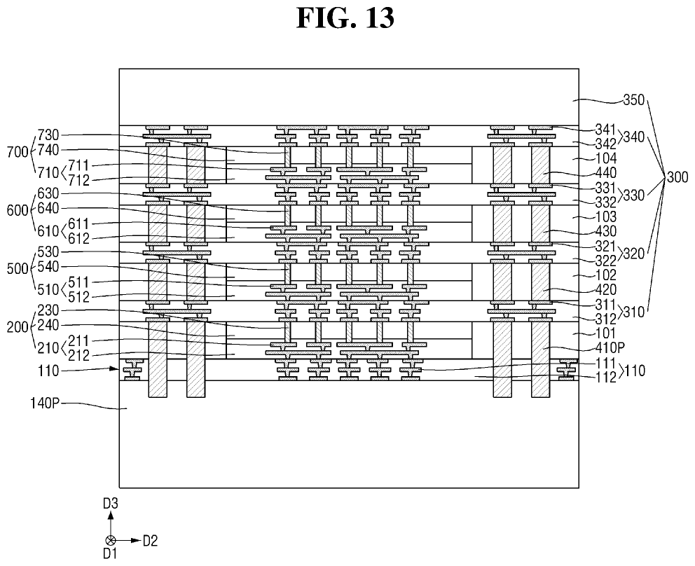

Referring to FIG. 13, the fifth power wiring structure 340 and the power wiring substrate 350 may be formed.

Subsequently, referring to FIG. 2, FIG. 7 and FIG. 8, the first through-via 130 and the first power connection pillar 410 may be formed. Subsequently, the first power wiring structure 120 and the lower pad 180 may be formed.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A semiconductor package comprising:
a first semiconductor chip including a first signal wiring structure forming a first surface thereof, and a first power wiring structure forming a second surface thereof, wherein the second surface is opposite the first surface;
a second semiconductor chip disposed on the first signal wiring structure and including a second signal wiring structure;
a second power wiring structure disposed on the second semiconductor chip; and
a first power connection pillar electrically connecting the first power wiring structure to the second power wiring structure.

2. The semiconductor package of claim 1, further comprising a power wiring substrate disposed on the second power wiring structure.

3. The semiconductor package of claim 1, wherein the first semiconductor chip further includes a first through-via electrically connected to the first signal wiring structure and the first power wiring structure,
wherein the second semiconductor chip further includes a second through-via connected to the second signal wiring structure and the second power wiring structure.

4. The semiconductor package of claim 1, further comprising a molding film disposed between the second power wiring structure and the first signal wiring structure,
wherein the molding film surrounds the second semiconductor chip, and
wherein the first power connection pillar extends through the molding film.

5. The semiconductor package of claim 1, wherein a width of the second signal wiring structure is smaller than a width of the first signal wiring structure.

6. The semiconductor package of claim 1, wherein a width of the second signal wiring structure is smaller than a width of the second power wiring structure.

7. The semiconductor package of claim 1, wherein an upper surface of the first power connection pillar is in electrical contact with a lower surface of the second power wiring structure,
wherein a lower surface of the first power connection pillar is in contact with an upper surface of the first power wiring structure.

8. The semiconductor package of claim 1, further comprising an outer bump on the second surface of the first semiconductor chip and electrically connected to the first power wiring structure.

9. The semiconductor package of claim 1, wherein the first power connection pillar extends through the first signal wiring structure.

10. The semiconductor package of claim 1, wherein the first power connection pillar is spaced apart from the second semiconductor chip in a first direction and extends in a second direction intersecting the first direction.

11. The semiconductor package of claim 1, wherein an upper surface of the first signal wiring structure and a lower surface of the second signal wiring structure are in physical contact with each other.

12. The semiconductor package of claim 1, further comprising:
a third semiconductor chip including a third signal wiring structure disposed on the second power wiring structure;
a third power wiring structure disposed on the third semiconductor chip; and
a power wiring substrate disposed on the third power wiring structure.

13. The semiconductor package of claim 12, further comprising a second power connection pillar electrically connecting the second power wiring structure to the third power wiring structure.

14. The semiconductor package of claim 12, further comprising a third power connection pillar electrically connecting the first power wiring structure to the third power wiring structure,
wherein the third power connection pillar extends through the first signal wiring structure and the second power wiring structure.

15. The semiconductor package of claim 11, wherein the first semiconductor chip is an application processor chip or a logic chip,
wherein the second semiconductor chip is a memory chip.

16. A semiconductor package comprising:
a first semiconductor chip including a first through-via;
a second semiconductor chip disposed on the first semiconductor chip and including a second through-via;
a power wiring substrate disposed on the second semiconductor chip; and
a power connection pillar electrically connecting the first semiconductor chip to the power wiring substrate,
wherein the first semiconductor chip includes a first signal wiring structure disposed on a top surface of the first through-via, and a first power wiring structure disposed on a bottom surface of the first through-via,
wherein the second semiconductor chip includes a second signal wiring structure disposed on a bottom surface of the second through-via, wherein the second signal wiring structure contacts the first signal wiring structure,
wherein the power wiring substrate includes a second power wiring structure disposed on the second through-via,
wherein the power connection pillar extends between the first power wiring structure and the second power wiring structure, and
wherein the power connection pillar is disposed outwardly of the second semiconductor chip.

17. The semiconductor package of claim 16, wherein a width of the second semiconductor chip is smaller than each of a width of the first semiconductor chip and a width of the power wiring substrate.

18. The semiconductor package of claim 16, wherein the power connection pillar extends through the first signal wiring structure.

19. The semiconductor package of claim 16, wherein a lower surface of the power connection pillar is coplanar with a lower surface of the first through-via,
wherein an upper surface of the power connection pillar is coplanar with a upper surface of the second through-via.

20. A semiconductor package comprising:
a first semiconductor chip including:
a first signal wiring structure forming an upper surface thereof;
a first power wiring structure forming a lower surface thereof; and
a first through-via electrically connected to the first signal wiring structure and the first power wiring structure;
a second semiconductor chip including:
a second signal wiring structure disposed on the first signal wiring structure; and
a second through-via connected to the second signal wiring structure;
a second power wiring structure disposed on the second semiconductor chip and electrically connected to the second through-via;
a molding film disposed between the second power wiring structure and the first signal wiring structure that surrounds the second semiconductor chip;
a power connection pillar extending through the molding film, and electrically connecting the first power wiring structure to the second power wiring structure;
a power wiring substrate disposed on the second power wiring structure; and
an outer bump disposed on a bottom surface of the first semiconductor chip and electrically connected to the first power wiring structure,
wherein a width of the second power wiring structure and a width of the power wiring substrate are equal to each other.
